(19) United States
(12) Patent Application Publication
(10) Pub. No.: US 2010/0232132 A1
(43) Pub. Date: Sep. 16, 2010

(54) Flexible Transponder Holder

(75) Inventor: David Centner, Great Neck, NY (US)

Correspondence Address: HOFFMANN & BARON, LLP, 6900 JERICHO TURNPIKE, SYOSSET, NY, 11791, US

(73) Assignee: HIGHWAY TOLL ADMINISTRATION, LLC, Great Neck, NY (US)

(21) Appl. No.: 12/404,922

(22) Filed: Mar. 16, 2009

(51) Int. Cl. H05K 5/02; A47B 96/06; A47F 5/00

(52) U.S. Cl. 361/814; 248/205.1; 248/206.2; 248/208

(57) ABSTRACT

A transponder holder securable to a support surface includes a transponder mounting surface defining a plane. An attachment member removably connects the mounting surface to the support surface. A connecting member extends between the attachment member and the mounting surface. The connecting member having a first portion operably connected to the attachment member and a second portion operably connected to the mounting surface. The second portion is offset from the first portion in a direction generally perpendicular to the plane of the mounting surface.

The present invention relates to an apparatus for supporting a wireless device, and more particularly a receptacle for supporting a toll paying device.

### BACKGROUND OF THE INVENTION

The use of electronic toll collection systems is becoming evermore popular as a way of managing traffic volume through toll collection points. Such systems typically include a reader at the toll station which interrogates a wireless payment device located on a vehicle. The payment device may be a transponder, such as an RFID (radio frequency identification device). Upon interrogation by a reader, the transponder emits a radio frequency signal that includes information corresponding to an account code unique to the transponder. Therefore, the user can be properly charged for going through the toll. Such transponders are marketed by Mark IV Transportation Technologies Group and TransCore. The transponders operate with toll collection systems such as E-ZPASS® and SunPass®. In order to function properly, the transponder must be in radio frequency (“RF”) communication with the interrogator. If this communication is interrupted, the transponder will not be acknowledged. Therefore, the transponder is typically located on the windshield or other part of the vehicle where it is unobstructed by the metal body of the vehicle.

At times it may be desirable for a driver of a vehicle to pay for the toll directly and not rely upon the payment device in the vehicle. For example, if the driver has rented the car from a rental company, the driver may prefer to pay the toll themselves as opposed to relying on the transponder provided with the rental car. In such cases the driver may remove the toll paying device and place it in a container which blocks the transmission of radio waves.

Transponders also are available as a thin flexible device having an adhesive backing which are typically referred to as sticker tags or peel-and-stick style tags. Such tags may be shaped somewhat like a credit card. The sticker tag transponder is mounted directly to the windshield. Direct contact with the windshield is important so that the transponder can be properly interrogated by a toll collecting system. Temporary removal of such transponders in order to prevent them from being interrogated is generally not possible. Removal from the windshield typically damages the transponder's antenna, thereby effectively destroying its transmission capabilities. Therefore, a user cannot prevent interrogation of the tag. In addition, mounting a peel-and-stick type transponder directly to a vehicle's windshield makes it virtually impossible to move the transponder between different vehicles.

Accordingly, it would be desirable to provide a holder for supporting a thin, flexible transponder which permits it to be easily attached and removed from a vehicle.

### SUMMARY OF THE INVENTION

The prevent invention provides a device for supporting a transponder.

The present invention further provides a device for removably supporting a transponder on a vehicle.

The present invention also provides a transponder holder securable to a support surface including a transponder mounting surface defining a plane. An attachment member removably connects the mounting surface to the support surface. A connecting member extends between the attachment member and the mounting surface. The connecting member has a first portion operably connected to the attachment member and a second portion operably connected to the mounting surface. The second portion is offset from the first portion in a direction generally perpendicular to the plane of the mounting surface.

The present invention further provides a transponder holding system including a support surface and a transponder holder including a mounting surface lying in and defining a plane. An attachment member removably connects the mounting surface to the support surface. A connecting member extends between the attachment member and the mounting surface. The connecting member has a first portion operably connected to the attachment member and a second portion operably connected to the support surface. The second portion is offset from the first portion in a direction generally perpendicular to the plane. A transponder is fixedly secured to the mounting surface. The transponder is supported in contact with the support surface.

The present invention still further provides a method of supporting a transponder including,

obtaining a transponder holder including a transponder mounting surface defining a plane, an attachment member for removably connecting the mounting surface to the support surface, and a connecting member extending between the attachment member and the support surface, the connecting member having a first portion operably connected to the attachment member and a second portion operably connected to the mounting surface, the second portion being offset from the first portion in a direction generally perpendicular to the plane;

mounting a transponder to the mounting surface; and

removably attaching the holder to a vehicle's windshield.

### BRIEF DESCRIPTION OF THE DRAWINGS

FIG. 1 is a perspective view of one embodiment of a holder of the present invention.

FIG. 2 is a side elevational view of the holder of FIG. 1 attached to a support surface.

FIG. 3 is a front elevational view of the holder of FIG. 1.

FIG. 4 is a perspective view of an alternative embodiment of a holder of the present invention.

FIG. 5 is an exploded perspective view of the holder of FIG. 4.

FIG. 6 is a side elevational view of the holder of FIG. 4 shown attached to a support structure.

FIG. 7 is an exploded perspective detail view of a securement device of the holder of FIG. 4.

### DETAILED DESCRIPTION OF THE PREFERRED EMBODIMENTS

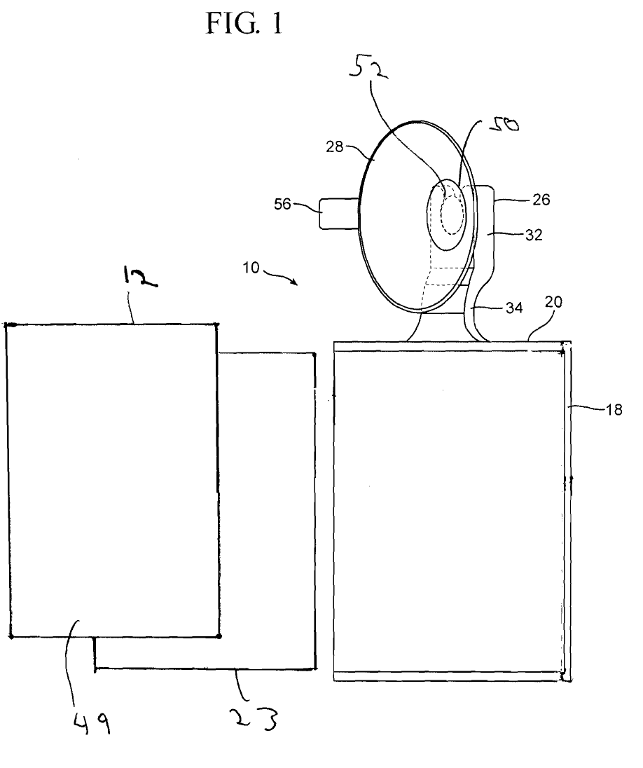

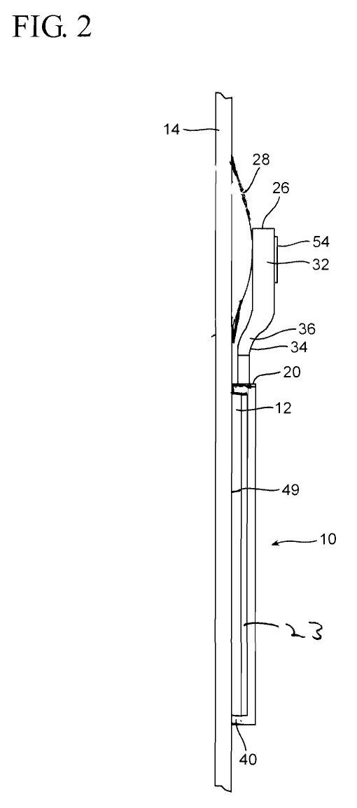

With reference to FIGS. 1 and 2, the present invention provides a holder 10 for a transponder 12. The transponder 12 may be of a type used, for example, in connection with an automated toll system or a vehicle parking system. Such systems may include a reader which remotely interrogates the transponder and reads the information emitted thereby. The transponder 12 may take the form of a thin, flexible member commonly referred to as a sticker tag or peel-and-stick tag. The transponder 12 includes an antenna for communicating with the reader. The transponder 12 provides the reader with a signal unique to the particular transponder. The holder 10 of the present invention permits the transponder 12 to be removably attached to a support structure 14 such as a windshield of a vehicle.

With reference to FIGS. 1-3, holder 10 includes a transponder mounting plate 18 having a transponder mounting surface 21. Mounting surface 21 may be a generally planar solid surface. The mounting plate 18 may be bounded at its perimeter by a rim 20. The mounting surface 21 may be bounded at its upper and lower edges by a raised lip 22 extending from mounting surface 21. The lips 22 and mounting surface 20 define a space 24 for receiving therein the transponder 12. An adhesive layer 23 may be disposed between a back side of the transponder 12 and the mounting surface 21 in order to fixably secure the transponder 12 to the mounting surface. The adhesive layer 23 may be secured to the mounting surface 21 and may have a release sheet (not shown) on its surface facing the transponder 12 which when removed exposes adhesive material to which the transponder 12 may be secured. Mounting plate 18 may have a dimensional configuration substantially the same as the configuration of the transponder 12. The mounting surface 21 may be a substantially planar, solid, flat member. Accordingly, the transponder 12 is supported along its entire width and length.

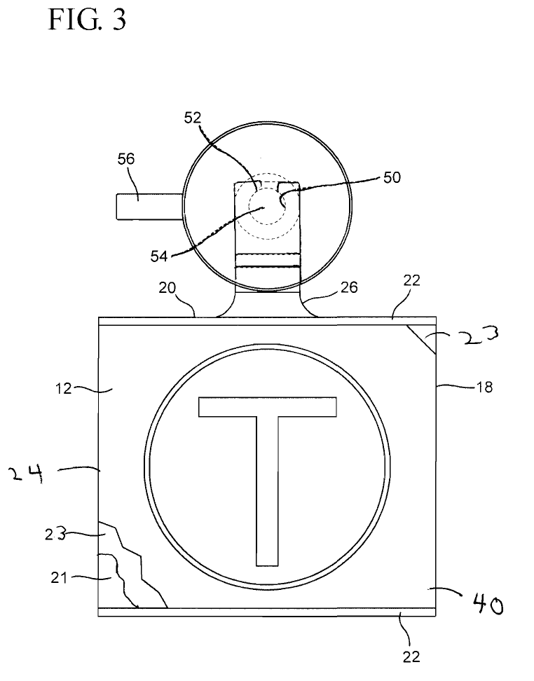

Holder 10 may further include a connecting member 26 extending from the rim 20 of plate 18. Connecting member 26 may be a relatively thin neck-like member that connects the plate 18 to an attachment member 28. Holder 10 may be formed of a molded plastic material with the plate 18 and connecting member 26 being integrally formed. Alternatively, the holder 10 may be formed of other materials such as metal. The attachment member 28 permits the holder 10 to be removably secured to the support structure 14 such as the windshield of a vehicle (FIG. 3). The connecting member 26 includes a first portion 32 operably connected to the attachment member 28. The first portion may be a generally straight member. Extending from the first portion 32 is a second portion 34 which is fixedly secured to the upper edge of the plate 18. The second portion 34 of the connecting member may have a generally curved configuration which smoothly extends from the first portion 32. In the mounting of transponders such as sticker tags, it is desirable to have the transponder 12 pressed directly against the windshield to ensure that the transponder will be properly interrogated by the reader. Accordingly, the connecting member 26 preferably has a curved offset 36 from the first portion 32 such that the plate 18 and the transponder 12 secured to the mounting surface is offset in a direction toward the support surface 14. The plate 18 forms a plane 40 and the offset is in a direction substantially perpendicular to plane 40. The mounting surface 20 is offset such that it projects from the first portion 32 in the same direction as the attachment member 28 projects. The offset 36 accommodates the thickness of the attachment member 28 when connected to the support surface 14 and permits the transponder to be disposed flush against the support surface 14.

As shown in FIG. 2, the connector second portion 34 is offset from the first portion 32. Accordingly when the attachment member is secured to support surface 14, a transponder exterior surface 49 is pressed against the support surface 14. Preferably, the transponder exterior surface 49 contacts the support surface 14 over substantially the entire exterior surface. In this way, the transponder's antenna may reliably communicate with a reader.

Connecting member first portion 32 may include a U-shaped slot 50 (FIG. 3) having a narrow neck area 52. Slot 50 is sized to receive a round-end lug 54 extending from the attachment member 28. In one embodiment, attachment member 28 may be one or more suction cups. The suction cup may be formed of an elastomeric material that has round lugs extending from the back in a manner well known in the art. Lug 54 may extend within the slot 50 of the connecting member and be captured therein. The suction cup may include a tab 56 extending from an outer edge thereof in order to help release the suction cup from a support surface to which it is attached. It is also within the contemplation of the present invention that the attachment member could include an adhesive, hook and loop fastener, or any other connecting device for securing a member to a support surface.

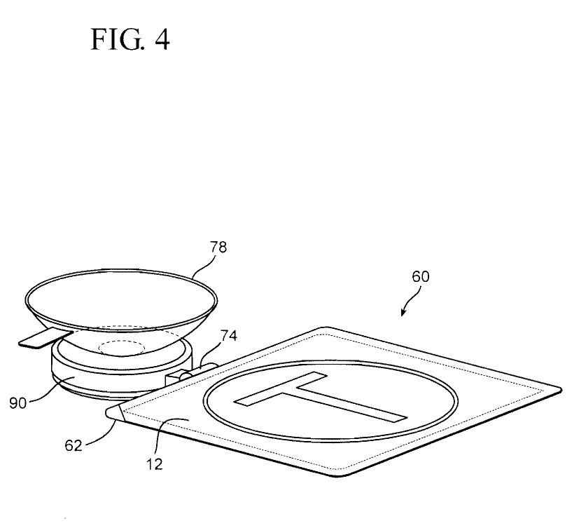

With reference to FIGS. 4-7, an alternative embodiment of the present invention is shown. Holder 60 may include a mounting member 62 formed of spaced elongate elements 64 connected together forming a frame 66. The frame defines a central opening 68. The frame 66 has a configuration corresponding to the outer periphery of the transponder 12. Frame 66 may form a mounting surface 70 to which the transponder 12 is attached. The frame 66 may also support one or more adhesive tabs 72 which may be attached to the spaced elements 64. The adhesive tabs 72 may be covered by a release sheet (not shown) which when removed exposes adhesive material. Adhesive tabs 72 form a layer having an adhesive surface to which the transponder 12 may be secured. Accordingly, the transponder 12 is fixedly secured to the mounting surface 70 of the frame. Alternatively, the adhesive for securing the transponder to the frame 66 may be formed as part of the transponder 12.

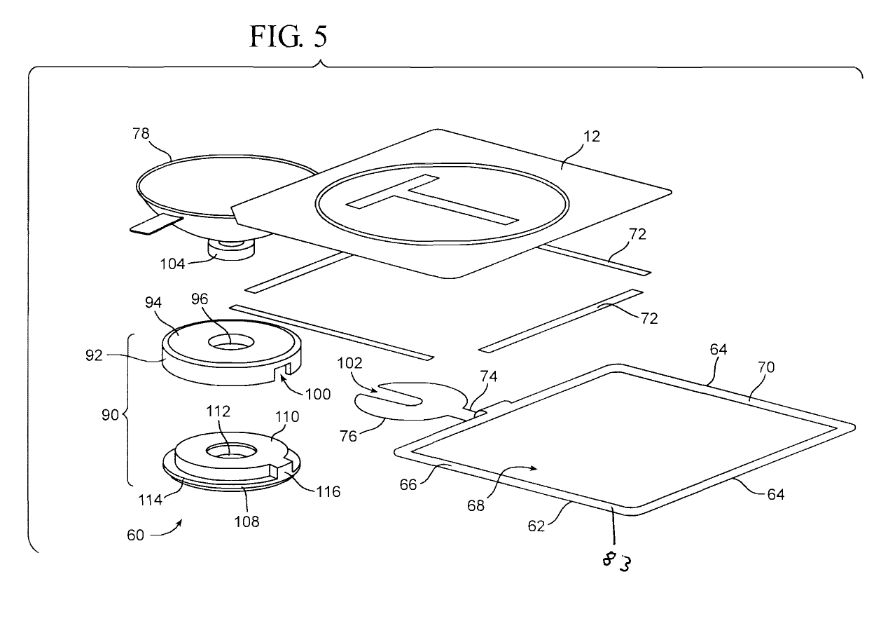

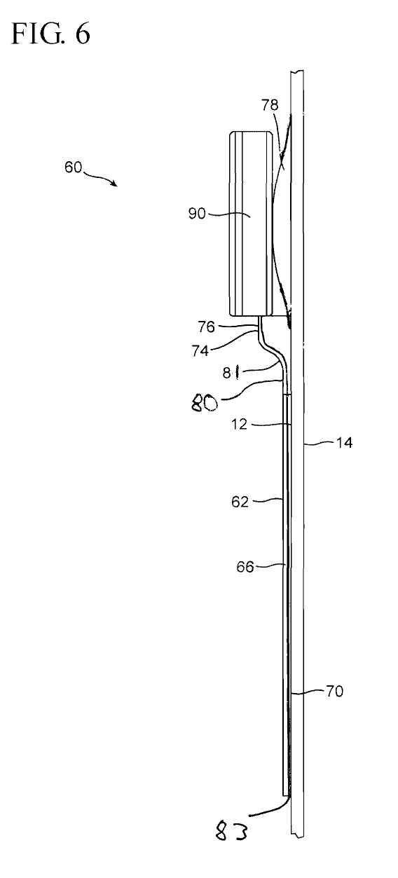

With specific reference to FIGS. 5 and 6, a connecting member 74 extends from an upper portion of the frame 66. Frame 66 and connecting member 74 may be integrally formed from a sheet of thin metal material, which is processed by stamping or cutting, or alternatively, of a molded plastic material. The connecting member 74 may include a first portion 76 operably connected to an attachment member 78. Attachment member 78 extends outwardly from the first portion 76. The connecting member may further include a second portion 80 fixedly attached to the frame 66. Between the first and second connecting members is a curved offset portion 81. Accordingly, the first portion 76 is offset from the mounting surface 70 in a direction generally perpendicular to a plane 83 in which the transponder supporting mounting surface 70 lies. The mounting surface 70 is offset such that it projects from the first portion in the same direction as the attachment member 78 projects. This offset accommodates the thickness of the attachment member 78. Accordingly, when the holder 60 is attached to a support surface 14, the mounting surface 70 and the transponder 12 attached thereto lie against the support surface 14.

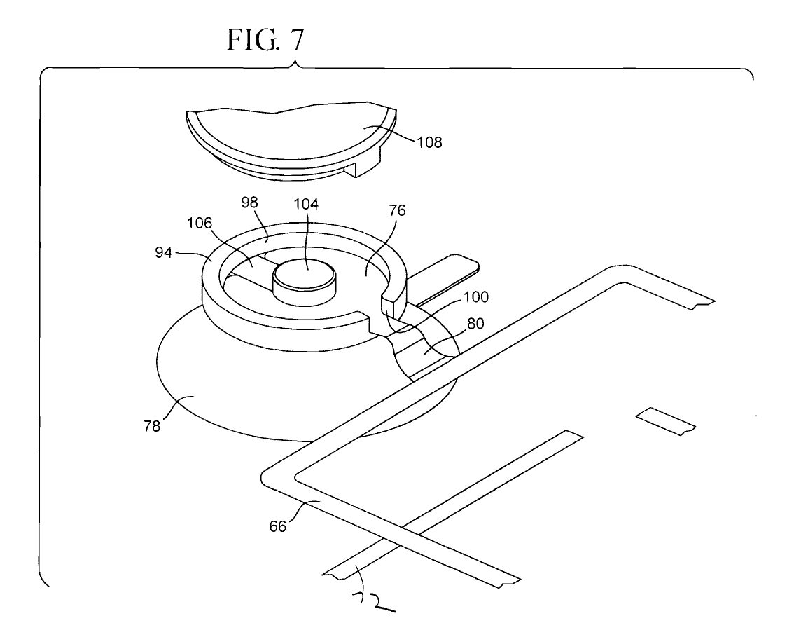

A securement device 90 operably connects the attachment member 78 to the connecting member 74. Specifically, the securement device 90 forms an annularly-shaped housing 92 having a base 94 including an opening 96 extending axially therethrough. With specific reference to FIG. 7, the base 94 is bounded by an upwardly extending wall 98 which includes an interruption causing a gap 100 in the wall. The base 94 accommodates the first portion 76 of the connecting member which may sit therein. A section of the first portion sits within gap 100. The first portion 76 includes at its distal end an elongated U-shaped channel 102 which partially surrounds the base opening 96. The attachment member 78, which may include a suction cup, has an outwardly projecting lug 104 which may extend upwardly through the base opening 96 and be captured by the U-shaped channel 102 in the connecting member first portion 76. The resilient nature of the suction cup and the lug 104 provide for a tight fit in the U-shaped channel 102. The base 94 may include a raised ridge 106 radially extending from the opening 96. Ridge 106 may be sized and shaped to fit within a portion of channel 102 as shown in FIG. 7.

A cap 108 may be secured to the housing 92 in order to securely retain the connecting member first portion 76 therein. The cap 108 may include a body 110 having an opening 112 therein. Body 110 may be sized such that it fits within the wall 98 of the housing 92. The opening 112 accommodates the lug 104 of the attachment member. A flange 114 may extend outwardly from the body 110 and sits on top of wall 98 when the cap 108 is secured to the housing 92. Extending radially from the body 110 is a tab 116 which may be inserted in the gap 100. The tab 116 forms a backing to the connecting member and helps to support it therein. The cap may be retained to the housing 92, for example, by an interference fit and/or by an adhesive.

The method of using the holder of the present invention will be described in association with holder 60; however, the method of use would be substantially the same for the holder 10 described above. The transponder 12 may be attached to the mounting surface by removing the release sheet to expose the adhesive material on the adhesive tabs 72. The transponder 12 may then be fixed to the mounting surface 70. In order to install the holder 60, a user may align the holder on the support 14, such as a windshield, and press the cap 108 thereby forcing the attachment member 78, such as a suction cup, to engage the windshield and become removably attached thereto. In the mounted position, the transponder 12 engages the windshield. Accordingly, the transponder 12 may be properly interrogated by a reader such as used in an automated toll collection system.

The holder 60 may be easily removed by releasing the attachment member 78. Accordingly, the holder 60 along with the transponder 12 may be moved to another vehicle or may be removed from the vehicle when not in use. Furthermore, if a driver desires to go through a toll area and pay the toll manually without use of the transponder 12, the transponder may be placed in a location where it will not be interrogated and read by the toll sensing device. Accordingly, the operator of the vehicle is given an option whether to use the transponder 12 for automatic payment or to pay manually.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

1. A transponder holder securable to a support surface comprising:
a transponder mounting surface defining a plane;
an attachment member for removably connecting the mounting surface to the support surface; and
a connecting member extending between the attachment member and the mounting surface, the connecting member having a first portion operably connected to the attachment member and a second portion operably connected to the mounting surface, the second portion being offset from the first portion in a direction generally perpendicular to the plane of the mounting surface.

2. The holder as defined in claim 1, wherein the mounting surface is a plate-like member.

3. The holder as defined in claim 1, wherein the mounting surface is bounded along its perimeter by a rim and the connecting member extends outwardly from the rim.

4. The holder as defined in claim 1, wherein the offset is sized such that the transponder mounting surface is disposed adjacent the mounting surface when the attachment member is attached to the mounting surface.

5. The holder as defined in claim 1, wherein the mounting surface is a solid planar surface adapted to receive a flexible transponder thereon.

6. The holder as defined in claim 1, wherein the mounting surface includes a frame having an open center.

7. The holder as defined in claim 1, wherein the attachment member includes a suction cup.

8. The holder as defined in claim 7, wherein the connecting member first portion includes a groove for receiving the attachment member.

9. The holder as defined in claim 1, wherein the attachment member is operably connected to the first portion of the connecting member by a securement device having an opening for receiving a portion of the attachment member.

10. The holder as defined in claim 9, wherein the housing receives the first portion of the connecting member and the groove in the first portion securingly engages the portion of the attachment member.

11. The holder as defined in claim 1, further including an adhesive layer disposed on the mounting surface for fixedly securing the transponder thereto.

12. A transponder holding system comprising:
a support surface;
a transponder holder including a mounting surface lying in and defining a plane;
an attachment member for removably connecting the mounting surface to the support surface;
a connecting member extending between the attachment member and the mounting surface, the connecting member having first portion operably connected to the attachment member and a second portion operably connected to the support surface, the second portion being offset from the first portion in a direction generally perpendicular to the plane; and
a transponder fixedly secured to the mounting surface, the transponder being supported in contact with the support surface.

13. The system as defined in claim 12, wherein the support surface includes a windshield of a vehicle.

14. The system as defined in claim 12, wherein the transponder is a flexible member.

15. The system as defined in claim 14, further including an adhesive layer disposed between the mounting surface and the transponder for fixing the transponder to the mounting surface.

16. The system as defined in claim 12, wherein the transponder holder includes a planar plate which forms the mounting surface.

17. The system as defined in claim 12, wherein the transponder has an exterior surface which contacts the support surface over substantially the entire exterior surface.

18. A method of supporting a transponder comprising:
obtaining a transponder holder including a transponder mounting surface defining a plane, the transponder holder including an attachment member for removably connecting the mounting surface to the support surface, and including a connecting member extending between the attachment member and the support surface, the connecting member having a first portion operably connected to the attachment member and a second portion operably connected to the mounting surface, the second portion being offset from the first portion in a direction generally perpendicular to the plane;
mounting a transponder to the mounting surface; and
removably attaching the holder to a vehicle's windshield wherein the transponder engages the windshield.

19. The method as defined in claim 18, further including securing the transponder to the mounting surface using an adhesive layer.

20. The method as defined in claim 19, further including removing the holder from the windshield.
